(19) United States
(12) Patent Application Publication
(10) Pub. No.: US 2007/0035939 A1
(43) Pub. Date: Feb. 15, 2007

(54) Reduced cost conductive interface

(76) Inventors: Patrick Joseph Wallace, San Jose, CA (US); Errol Dudas, San Jose, CA (US)

Correspondence Address: FAY KAPLUN & MARCIN, LLP, 15O BROADWAY, SUITE 702, NEW YORK, NY, 10038, US

(21) Appl. No.: 11/204,592

(22) Filed: Aug. 15, 2005

(51) Int. Cl. H05K 9/00

(52) U.S. Cl. 361/816

(57) ABSTRACT

A device comprises a printed circuit board including a plurality of electric components mounted thereto and a shielding element for one of shielding the electric components from electric signals outside the device and shielding electric components outside the device from electric signals within the device in combination with an elastomeric gasket forming a first electrically conductive path between the shielding element and a contacting surface of the gasket and a spacer element a first surface of which contacts the printed circuit board, a second surface of the spacer element contacting the contacting surface of the gasket, the spacer element defining a second electrically conductive path between the first and second surfaces thereof to couple the first and second electrically conductive paths to electrically couple the shielding element to the printed circuit board.

### BACKGROUND INFORMATION

Components of an electronic device which enable the device to perform its functions (e.g., internal circuitry) are often referred to as critical components. Such critical components including, for example, discrete and integrated components, are typically arranged in close configuration on a circuit board. Often it is required that the circuit board and the critical components be disposed within shielding structures to prevent unwanted electrical emissions from seeping out or in. It is also often required that the critical components be disposed below electrical circuit signals or grounding paths of the circuit board.

Also included in the circuit board are contact positions, which are necessarily connected to a variety of other structures. The contact positions are particularly useful for shielding and grounding functions and are generally formed of materials of relatively high conductivity and corrosion resistance. However, the contact positions are often required to be placed around the critical components, and thus may be difficult to access.

A printed circuit assembly may directly incorporate conductive and/or corrosion resistant materials directly into its structure in order to form the contact positions. However, such integration results in high production and replacement costs.

### SUMMARY OF THE INVENTION

The present invention is directed to a device comprising a printed circuit board including a plurality of electric components mounted thereto and a shielding element for one of shielding the electric components from electric signals outside the device and shielding electric components outside the device from electric signals within the device in combination with an elastomeric gasket forming a first electrically conductive path between the shielding element and a contacting surface of the gasket and a spacer element a first surface of which contacts the printed circuit board, a second surface of the spacer element contacting the contacting surface of the gasket, the spacer element defining a second electrically conductive path between the first and second surfaces thereof to couple the first and second electrically conductive paths to electrically couple the shielding element to the printed circuit board.

### BRIEF DESCRIPTION OF THE DRAWINGS

FIG. 1 is an exemplary embodiment of a system according to the present invention;

FIG. 2A is an exemplary embodiment an open circuit system according to the present invention;

FIG. 2B is an exemplary embodiment of a closed circuit system according to the present invention;

FIG. 3A is another exemplary embodiment of a system according to the present invention;

FIG. 3B is another exemplary embodiment of a system according to the present invention; and

FIG. 3C is another exemplary embodiment of a system according to the present invention.

### DETAILED DESCRIPTION

The present invention may be further understood with reference to the following description and the appended drawings, wherein like elements are provided with the same reference numerals. The present invention provides a system to electrically couple contact points on a printed circuit board (“PCB”) to a secondary structure.

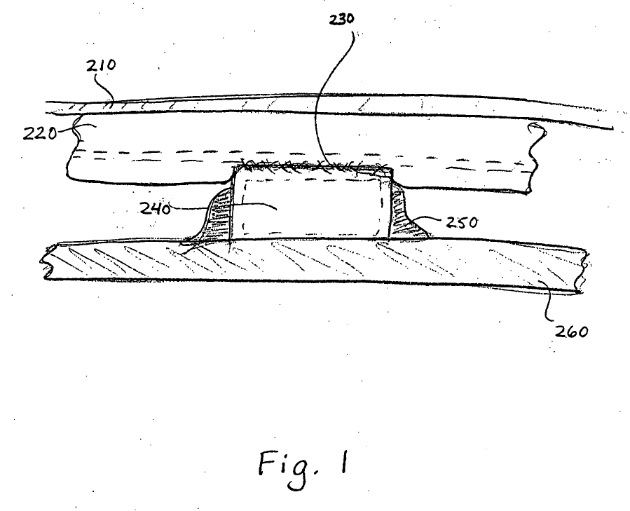

As shown in FIG. 1 an exemplary embodiment of the device according to the present invention includes a spacer element (e.g., an interface 240) mounted on a PCB 260. The interface 240 is secured to the PCB 260, for example, with solder 250. The interface 240 contacts an electrically conductive elastomeric gasket 220 at a contact surface 230. The elastomeric gasket 220 also contacts a structure 210 to which it is secured by for example, adhesive, compression, mechanical fasteners, etc. To simplify manufacturing, the interface 240 is preferably sized and shaped similarly to other components coupled to the PCB 260. For example, the interface 240 may be equivalent in size to an “0603” surface mount component, measuring 0.060″L×0.030″W×0.030″H.

The interface 240 is made from one or more materials, at least one of which is conductive. For instance, the interface may be substantially composed of a non-conductive material, such as plastic, with selected portions of the surface coated with a highly conductive material, such as gold. Those skilled in the art will understand that the coated portions may be limited to those areas which are required to conduct electricity. Specifically, all or a part of a surface of the interface 240 which contacts the conductive elastomeric gasket 220 will be coated with conductive material as will all or part of the surface of the interface 240 which contacts the PCB 260. Furthermore, one or more paths of conductive material will join these areas of electrical contact between the interface 240 and the gasket 220 and between the interface 240 and the PCB 260. Alternatively, the interface 240 may be a mass formed of one or more conductive materials. In a further exemplary embodiment, the interface 240 may be formed of one or more conductive materials with a hollow core. As would be understood by those of skill in the art, the conductive material(s) used in any of these embodiments will preferably be selected based on cost and/or desired performance criteria. For example, lead/tin, copper, gold, silver, or any other conductive material may be used.

Before the solder 250 is applied to the PCB 260 to secure the interface 240, the PCB 260 may be coated. The coating may be applied to exposed metal portions of the PCB 260, and may be any of a variety of types. For example, the coating may be organic solder preservative (“OSP”), electroless nickel/immersion gold (“ENIG”), immersion tin, immersion silver, etc. In a conventional system, the coating may serve as the electrical coupling between the PCB and the elastomeric gasket, and thus the coating would have to be highly conductive. However, according to the present invention, an electrical connection between the PCB 260 and the elastomeric gasket 220 is provided by the interface 240. Thus, it is not necessary for the coating to provide the electrical coupling, and a lower cost coating with lower conductivity, such as OSP, may be used without being cleaned. Because the OSP does not require cleaning to enhance its conductivity, a manufacturing step is eliminated and manufacturing costs are decreased.

The elastomeric gasket 220 is preferably made of silicon rubber with a highly conductive silver fill dispersed throughout. However, any compliant material may be used to form the gasket 220. Further, any highly conductive material or assembly may be used in place of the silver fill.

The contact surface 230 includes a relative degree of contact resistance. Because the interface 240 is coated with corrosion resistant material, the degree of contact resistance will not degrade significantly over time. Integrity of the contact surface 230 is also enhanced as the interface 240 increases a surface area of the PCB 260 over which electrical contact is established.

The elastomeric gasket 220 may take a variety of shapes and forms. For instance, the elastomeric gasket 220 may cover an entire surface of the structure 210. Alternatively, the gasket 220 may be formed as one or more strips distributed along a surface of the structure 210. Further, the elastomeric gasket 220 may be formed in any of a variety of shapes. For example, the gasket 220 may be substantially rectangular, conical, etc. The interface 240 eliminates the need for the elastomeric gasket 220 to be designed to extend down to the PCB 260 and contorted and maneuvered around discrete and integrated electrical components.

The structure 210 may be used for a variety of applications. For example, the structure 210 may be used to shield components of the PCB 260 from electrical emissions of other components and/or to prevent the escape of electrical emissions produced by the components of the PCB 260 to surrounding areas. Alternatively, the structure 210 may serve as a ground for circuitry disposed on the PCB 260. The structure 210 may also serve as part of a signal path. Accordingly, the structure 210 is preferably formed of sheet metal or any other conductive material possessing suitable mechanical properties.

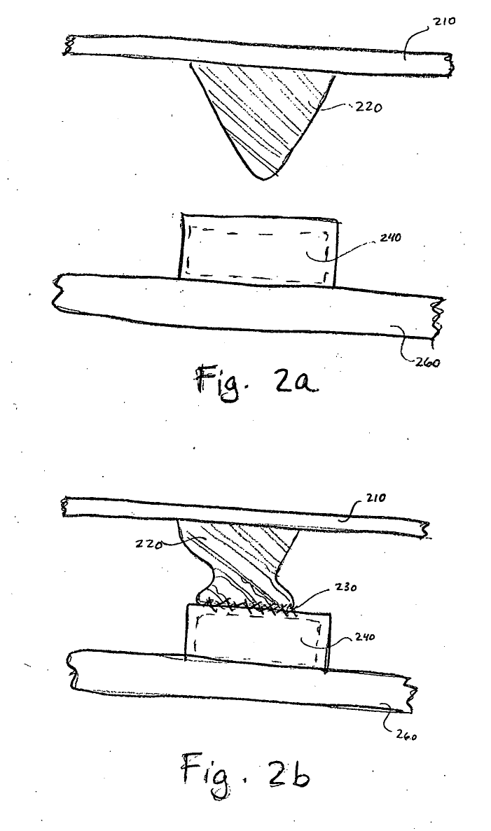

FIG. 2A shows an embodiment of the present invention wherein, before being deformed through contact with the interface 240, the elastomeric gasket 220 is substantially conical. As shown, the system is in an open circuit configuration with no conductive path between the PCB 260 and the structure 210. An end of the gasket 220 distal to the structure 210 is tapered. Accordingly, an extent of the contact surface 230 between the gasket 220 and the interface 240 may be varied by adjusting an amount of compression of the gasket 220 when assembled with the PCB 260. For example, in applications where it is desired that the interface 240 be relatively narrow, the gasket 220 will be compressed against the interface 240 only until a distal portion of the gasket 220 contacts the interface 240. Conversely, for applications requiring a wider interface 240 such as that portrayed in FIG. 2B, the structure 210 will be pressed against the PCB 260 until a wider portion of the gasket 220 is spread against the interface 240, as will be described below.

FIG. 2B shows the distal end of the gasket 220 after being flattened due to compression against the interface 240 increasing the length (and width) of the contact surface 230. As the degree of compression is increased, the area of the contact surface 230 increases.

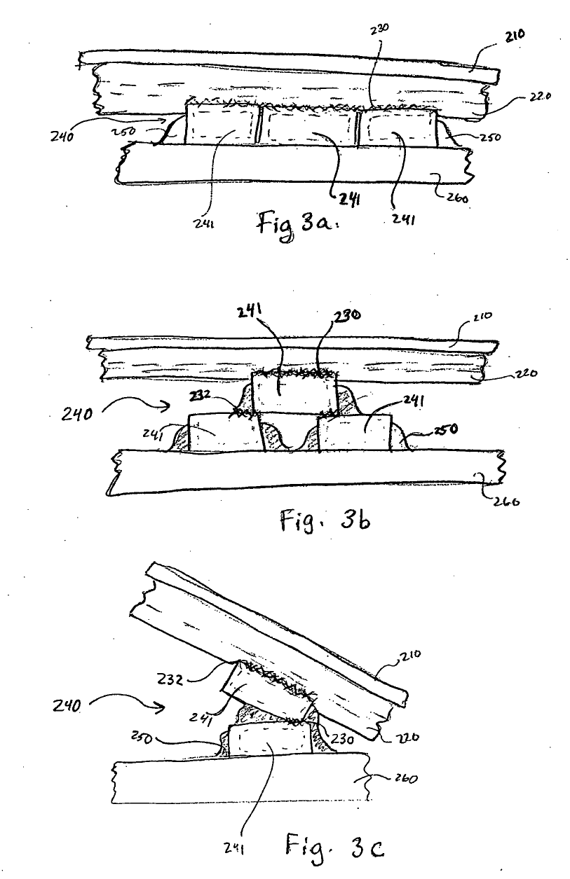

FIG. 3A shows an embodiment of the present invention where the interface 240 is comprised of a plurality of discrete interface elements 241. In this embodiment, the interface elements 241 are aligned in a nose-to-tail configuration. This configuration may prove beneficial in that it allows the size of each of the discrete interface elements 241 to be reduced. Further, the nose-to-tail configuration may provide improved shielding because there are relatively few gaps between the discrete interface elements 241, and any existing gaps are fairly small.

FIG. 3B shows an alternative embodiment of the present invention wherein the interface 240 is comprised of a plurality of discrete interface elements 241 stacked on one another. Specifically, as shown in FIG. 3B, a first interface element 241 is stacked on second and third interface elements 241 aligned similarly to the nose-to-tail configuration of FIG. 3A. The first interface element 241 is preferably secured and electrically coupled to the second and third interface elements 241 to ensure that the elements 241 will not shift relative to one another, disrupting the electrical connections therebetween. Accordingly, a first contact surface 232 exists between the first interface element 241 and the second interface element 241. In addition, a second contact surface 230 exists between the first interface element 241 and the elastomeric gasket 220.

FIG. 3C shows another alternative embodiment of the present invention wherein the interface 240 comprises a plurality of discrete elements 241. In this configuration, a first interface element 241 is positioned on the PCB 260 with a second interface element 241 stacked on the first interface element 241. However, this embodiment differs from that of FIG. 3B in that the second interface element 241 is positioned at a pitch with respect to the first interface 240. The pitch may be maintained, for example, by a mass of solder 250 disposed between the first and second interface elements 241. Similarly to the embodiment of FIG. 3B, first and second contact surfaces 230, 232 exist between the first and second interface elements 241 and the elastomeric gasket 220. The first contact surface 230 extends between the first and second interface elements 241 with the second contact surface 232 extending between the second interface element 241 and the gasket 220. This configuration is particularly suited for devices where the structure 210 is not intended to be parallel to the PCB 260.

The interface of the present invention facilitates the installation of electrical shielding, grounding, and signal contacts on conventional PCBs. Because of the highly conductive and corrosion resistant nature of the interface, the longevity and efficiency of the electrical connection between the PCB and a secondary component are significantly increased. Further, the installation is simplified and reduced in cost.

The present invention has been described with reference to the above exemplary embodiments. One skilled in the art would understand that the present invention may also be successfully implemented if modified. Accordingly, various modifications and changes may be made to the embodiments without departing from the broadest spirit and scope of the present invention as set forth in the claims that follow. The specification and drawings, accordingly, should be regarded in an illustrative rather than restrictive sense.

What is claimed is:

1. A device comprising:
a printed circuit board including a plurality of electric components mounted thereto;
a shielding element for one of shielding the electric components from electric signals outside the device and shielding electric components outside the device from electric signals within the device;
an elastomeric gasket forming a first electrically conductive path between the shielding element and a contacting surface of the gasket; and
a spacer element a first surface of which contacts the printed circuit board, a second surface of the spacer element contacting the contacting surface of the gasket, the spacer element defining a second electrically conductive path between the first and second surfaces thereof to couple the first and second electrically conductive paths to electrically couple the shielding element to the printed circuit board.

2. The device of claim 1, wherein the exposed portions of the printed circuit board are coated with organic solder preservative.

3. The device of claim 1, wherein the spacer element is substantially the same size as a first one of the components mounted on the printed circuit board.

4. The device of claim 3, wherein the first component is an 0603 surface mount component.

5. The device of claim 1, wherein the spacer element is secured to the gasket.

6. The device of claim 5, wherein the spacer element is secured to the gasket by one of an adhesive, compression and a mechanical fasteners.

7. The device of claim 1, wherein the spacer element is composed of a non-conductive material with a conductive coating on selected portions of a surface thereof.

8. The device of claim 7, wherein the spacer element is formed of plastic.

9. The device of claim 7, wherein the selected portions of the surface of the spacer element are coated with gold.

10. The device of claim 1, wherein the gasket is formed of a compliant material with a conductive fill dispersed therethrough.

11. The device of claim 10, wherein the compliant material is silicon rubber.

12. The device of claim 10, wherein the fill is silver.

13. The device of claim 1, wherein at least a portion of a surface of the spacer element is coated with a corrosion resistant material.

14. The device of claim 1, wherein an area of a first side of the gasket opposite the shielding element is compressed against the spacer element to spread from a pre-assembly configuration in which an area thereof is less than an area of a second side of the gasket contacting the shielding element.

15. The device of claim 14, wherein, in the pre-assembly configuration, the first side of the gasket is substantially conical.

16. The device of claim 1, further comprising a plurality of spacer elements mounted between the printed circuit board and the gasket.

17. The device of claim 16, wherein first and second ones of the plurality of spacer elements are mounted side by side on the printed circuit board.

18. The device of claim 17, wherein a third one of the plurality of spacer elements is mounted between the first and second spacer elements and the gasket.

19. The device of claim 1, wherein gasket and the spacer element are the printed circuit board and the shielding element are not parallel to one another and wherein the second surface of the spacer element is substantially parallel to the printed circuit board and the contacting surface of the gasket is substantially parallel to the shielding member.

20. The device of claim 19, wherein a mass of solder is applied to the second surface of the spacer element to maintain the contacting surface of the gasket at a desired angle relative thereto.

21. A method of making an electric device, comprising:
mounting an electrical component on a printed circuit board;
mounting a first spacer element on the printed circuit board, a first side of the spacer element being electrically coupled to the printed circuit board with an electrically conductive path extending from the first side to an electrically conductive portion of a second side of the spacer element;
mounting an elastomeric gasket on the second side of the first spacer element, an electrically conductive path extending through the gasket from an area of contact between the gasket and the first spacer element to a shield contacting side of the gasket; and
mounting a shielding member on the shield contacting side of the gasket to electrically couple the shielding member to the printed circuit board.

22. The method of claim 21, wherein the step of mounting the gasket on the first spacer element comprises compressing the gasket against the first spacer element to obtain a desired area of contact between the gasket and the first spacer element.

23. The method of claim 21, further comprising the step of applying a coating to a portion of the first spacer element.

24. The method of claim 21, further comprising the step of applying a coating to an entire surface area of the first spacer element.

25. The method of claim 23, wherein the coating is one of a conductive material and a corrosion resistant material.

26. The method of claim 21, further comprising the step of applying a coating to a portion of the printed circuit board.

27. The method of claim 26, wherein the coating is one of organic solder preservative, electroless nickel/immersion gold, immersion tin, and immersion silver.

28. The method of claim 21, further comprising the step of soldering the first spacer element to the printed circuit board.

29. The method of claim 21, wherein the step of mounting the elastomeric gasket on the second side of the first spacer element comprises compressing the gasket thereagainst.

30. The method of claim 29, further comprising varying an amount of compression of the gasket to alter a size of the area of contact between the gasket and the first spacer element.

31. The method of claim 21, further comprising mounting a second spacer element on the printed circuit board.

32. The method of claim 31, further comprising aligning the first and second spacer elements in a nose-to-tail configuration.

33. A method of making an electric device, comprising:
mounting an electrical component on a printed circuit board;
mounting a first spacer element on the printed circuit board, a first side of the spacer element being electrically coupled to the printed circuit board with an electrically conductive path extending from the first side to an electrically conductive portion of a second side of the spacer element;
mounting a second spacer element on the second side of the spacer element;
mounting an elastomeric gasket on the second spacer element, an electrically conductive path extending through the gasket from an area of contact between the gasket and the second spacer element to a shield contacting side of the gasket; and
mounting a shielding member on the shield contacting side of the gasket to electrically couple the shielding member to the printed circuit board.

34. The method of claim 21, further comprising mounting the first spacer element and the gasket at a pitch with respect to one another.
